(19) United States
(12) Patent Application Publication
(10) Pub. No.: US 2014/0144233 A1
(43) Pub. Date: May 29, 2014

(54) APPARATUS AND METHOD FOR AUTOMATIC GAIN CONTROL OF SENSOR, AND SENSOR APPARATUS

(71) Applicant: SAMSUNG ELECTRO-MECHANICS CO., LTD., Suwon-si (KR)

(72) Inventors: Kyung Rin KIM, Suwon-si (KR); Byoung Won HWANG, Suwon-si (KR); Chang Hyun KIM, Suwon-si (KR)

(73) Assignee: SAMSUNG ELECTRO-MECHANICS CO., LTD., Suwon-si (KR)

(21) Appl. No.: 14/088,136

(22) Filed: Nov. 22, 2013

(30) Foreign Application Priority Data
Nov. 26, 2012 (KR) 10-2012-0134454

(51) Int. Cl. H03G 3/20; G01P 15/08

(52) U.S. Cl. CPC H03G 3/20; G01P 15/08
USPC 73/504.12; 330/282; 73/514.35

(57) ABSTRACT

The present invention relates to an apparatus and a method for automatic gain control of a sensor, and a sensor apparatus. The apparatus for automatic gain control of a sensor including: a PID control unit for outputting a gain value applied compensated sensor signal by performing PID control while generating and changing a gain value to converge a peak value of a sensor signal to a target value; and a margin calculation unit for determining the degree of change of peaks of a previous gain value applied compensated sensor signal and a current gain value applied compensated sensor signal and performing calculation of a margin for stabilizing the compensated sensor signal according to the result of determination of the degree of change is provided. Further, a sensor apparatus and a method for automatic gain control of a sensor are provided.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2012-0134454, entitled filed Nov. 26, 2012, which is hereby incorporated by reference in its entirety into this application.

### BACKGROUND OF THE INVENTION

1. Field of the Invention

The present invention relates to an apparatus and a method for automatic gain control of a sensor, and a sensor apparatus, and more particularly, to an apparatus and a method for automatic gain control of a sensor that can minimize an automatic gain control error, and a sensor apparatus.

2. Description of the Related Art

Various sensors that sense movement or position of an ordinary object or external force generally have a resonant sensor mass to output a vibration output signal according to the movement or position of the object or the external force. At this time, the degree of stability of resonance of the sensor mass is one of very important factors that determine performance of the sensor. Since the sensor mass may resonate at an amplitude deviated from an initially set target value due to deterioration and changes of a MEMS structure of the sensor, apparatuses such as automatic gain control (AGC) are generally applied. The AGC is a method of automatically adjusting a resonance gain of a mass to always drive the sensor mass at an initial target value set for driving a sensor, and a method of applying a gain that can compensate resonance of a sensor mass as much as a difference by determining the difference between a current resonance state and a resonance target value is generally used.

In general, in the AGC, a current peak value converges to a target value through PID control to generate a gain for compensating a difference between the current peak value and the target value. At this time, in digitally controlling a MEMS structure, whether how close and stable the peak value can converge to the target value is a very important thing in determining performance of the AGC. However, in the AGC, the resonance of the sensor mass approaches the target value but continuously oscillates around the target value without completely converging to the target due to instability of a gain of the AGC caused by a difference between resolution of a peak value of an output signal of the sensor mass and resolution of the gain generated from an AGC operation or nonlinear instability of the resonance of the sensor mass even though converging to the target. Since this phenomenon may occur as noise of the entire system later and deteriorate output characteristics of the sensor, it must be removed.

In the conventional AGC system, in order to remove the above oscillation, a margin value selected from the outside is applied to overcome oscillation around a target. When a margin is set and an existing value converges within the margin so that the existing value is continuously maintained without applying a new margin any more, an AGC error as much as the margin may occur but oscillation can be removed. Therefore, it is a very important thing to determine a margin value that prevents oscillation after AGC while minimizing a target margin.

However, when determining a target margin value, it is difficult to adjust the target margin due to different resonance characteristics of the sensors and changes according to nonlinearity of the resonance characteristics. For all that, it is not realistic to set a margin by performing an AGC performance test for all sensor products. Therefore, in the prior art, AGC is tested by various sensors to perform stable AGC by applying a maximum margin that prevents oscillation after applying AGC.

However, this conventional method generates unnecessary performance degradation of AGC since a margin value larger than an actual margin is set in the sensor that doesn't need to set a value as much as a predetermined margin. On the contrary, even though a test is performed by various sensors, since the set margin can't represent the performance of all the sensors, there is always an anxiety that oscillation due to AGC is latent.

### RELATED ART DOCUMENT

### Patent Document

Patent Document 1: U.S. Pat. No. 5,805,212 (laid-open on Sep. 8, 1998)

### SUMMARY OF THE INVENTION

The present invention has been invented in order to overcome the above-described problems and it is, therefore, an object of the present invention to provide an apparatus and a method for automatic gain control of a sensor, and a sensor apparatus that can perform an AGC operation by calculating a margin in each AGC system itself and applying a minimum adaptive margin value.

Accordingly, it is an object of the present invention to minimize an AGC error by calculating and applying a margin adaptive to characteristics of each sensor in itself.

In accordance with a first embodiment of the present invention to achieve the object, there is provided an apparatus for automatic gain control of a sensor including: a PID control unit for outputting a gain value applied compensated sensor signal by performing PID control while generating and changing a gain value to converge a peak value of a sensor signal output as a vibration output signal according to movement or position of an object or external force to a target value; and a margin calculation unit for determining the degree of change of peaks of a previous gain value applied compensated sensor signal and a current gain value applied compensated sensor signal and performing calculation of a margin for stabilizing the compensated sensor signal in the PID control performing step according to the result of determination of the degree of change.

At this time, in an example, the margin calculation unit may not perform the calculation of the margin when a difference between a gap between the peak of the current gain value applied compensated sensor signal and the target value and a gap between the peak according to the previous gain value and the target value is out of a predetermined range and may perform the calculation of the margin when the difference is within the predetermined range and the peak values are approximate.

Further, in an example, the margin calculation unit may calculate the margin when the degree of change is within the predetermined range, the peak values are approximate, and the gap between the peak of the current gain value applied compensated sensor signal and the target value is within a preset maximum margin range.

At this time, the margin calculation unit may set the maximum gap among the gaps between the peak of the compensated sensor signal and the target value for a predetermined interval from when the gap between the peak of the current gain value applied compensated sensor signal and the target value is within the preset maximum margin range, as the margin.

Further, in accordance with an example, the margin calculation unit may include a gap difference calculation part for calculating the difference (Diff) between the gap (dₙ) between the peak of the current gain value applied compensated sensor signal and the target value and the gap (dₙ₋₁) between the peak according to the previous gain value and the target value; an AGC operation execution determining part for determining whether or not to execute the calculation of the margin by determining whether the gap difference (Diff) calculated by the gap difference calculation part is within the predetermined range and whether the gap (dₙ) according to the current gain value is within the preset maximum margin range; and a margin calculation part for setting the margin from the gap within the preset maximum margin range when the execution of the calculation of the margin is determined by the AGC operation execution determining part.

At this time, the AGC operation execution determining part may determine the execution of the calculation of the margin when the gap difference (Diff) is within the predetermined range and the gap (dₙ) according to the current gain value is within the preset maximum margin range, and may continuously perform the PID control without executing the calculation of the margin by generating and changing the gain value through the PID control unit when the gap difference (Diff) is out of the predetermined range or the gap (dₙ) according to the current gain value is out of the preset maximum margin range.

Further, in another example, when the AGC operation execution determining part determines whether the difference calculated by the gap difference calculation part is within the predetermined range, a reference of the predetermined range may be a range in which a ratio of the gap difference (Diff) to the gap (dₙ) according to the current gain value is 5%.

In accordance with another example, the margin calculation part may set the maximum gap among the gaps between the peak of the compensated sensor signal and the target value for the predetermined interval from when the gap (dₙ) according to the current gain value is within the preset maximum margin range, as the margin.

Further, in an example, the sensor signal output as a vibration output signal may be a gyro sensor signal.

Next, in accordance with a second embodiment of the present invention to achieve the object, there is provided a sensor apparatus including: a sensor mass for providing a vibration output according to movement or position of an object or external force; an analog circuit for generating and outputting an analog sensor signal by processing the vibration output of the sensor mass and providing a resonance signal to the sensor mass; an analog-digital conversion unit for converting the analog sensor signal into a digital signal; a digital control circuit for receiving the sensor signal converted into the digital signal, including a PID control unit for outputting a gain value applied compensated sensor signal by performing PID control while generating and changing the gain value to converge a peak value of the sensor signal output as the vibration output signal according to the movement or position of the object or the external force to a target value and a margin calculation unit for determining the degree of change of peaks of a previous gain value applied compensated sensor signal and a current gain value applied compensated sensor signal and performing calculation of a margin for stabilizing the compensated sensor signal according to the result of determination of the degree of change, and performing an automatic gain control operation according to the margin; and a digital-analog conversion unit for converting an output according to the operation performed by the digital control circuit into an analog signal to feed back the analog signal to the analog circuit.

At this time, in an example, the margin calculation unit of the digital control circuit may include a gap difference calculation part for calculating a difference (Diff) between a gap (dₙ) between the peak of the current gain value applied compensated sensor signal and the target value and a gap (dₙ₋₁) between the peak according to the previous gain value and the target value; an AGC operation execution determining part for determining whether or not to execute the calculation of the margin by determining whether the gap difference (Diff) calculated by the gap difference calculation part is within a predetermined range and whether the gap (dₙ) according to the current gain value is within a preset maximum margin range; and a margin calculation part for setting the margin from the gap within the preset maximum margin range when the execution of the calculation of the margin is determined by the AGC operation execution determining part.

Further, at this time, the margin calculation part may set the maximum gap among the gaps between the peak of the compensated sensor signal and the target value for a predetermined interval from when the gap (dₙ) according to the current gain value is within the preset maximum margin range, as the margin.

Further, in accordance with an example, the digital control circuit may further include a low-pass filter unit for receiving the sensor signal converted into the digital signal, removing noise of the received signal, and providing the noise-removed signal to the PID control unit.

Further, in an example, the sensor apparatus may be a gyro sensor apparatus.

Next, in accordance with a second embodiment of the present invention to achieve the object, there is provided a method for automatic gain control of a sensor, including: a PID control performing step of outputting a gain value applied compensated sensor signal by performing PID control while generating and changing a gain value to converge a peak value of a sensor signal output as a vibration output signal according to movement or position of an object or external force to a target value; and a margin calculation step of determining the degree of change of peaks of a previous gain value applied compensated sensor signal and a current gain value applied compensated sensor signal and performing calculation of a stabilization margin of the sensor signal applied to the PID control performing step according to the result of determination of the degree of change.

At this time, in an example, the margin calculation step may include a gap difference calculation step of calculating a difference (Diff) between a gap (dₙ) between the peak of the current gain value applied compensated sensor signal and the target value and a gap (dₙ₋₁) between the peak according to the previous gain value and the target value; an AGC operation execution determining step of determining whether or not to execute the calculation of the margin by determining whether the gap difference (Diff) calculated in the gap difference calculation step is within a predetermined range and whether the gap (dₙ) according to the current gain value is within a preset maximum margin range; and a margin setting step of setting the margin from the gap within the preset maximum margin range when the execution of the calculation of the margin is determined in the AGC operation execution determining step.

At this time, in the AGC operation execution determining step, the execution of the calculation of the margin may be determined when the gap difference (Diff) is within the predetermined range and the gap (dₙ) according to the current gain value is within the preset maximum margin range, and the calculation of the margin may not be performed when the gap difference (Diff) is out of the predetermined range or the gap (dₙ) according to the current gain value is out of the preset maximum margin range.

Further, in accordance with an example, in the margin setting step, the maximum gap among the gaps between the peak of the compensated sensor signal and the target value for a predetermined interval from when the gap (dₙ) according to the current gain value is within the preset maximum margin range may be set as the margin.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram schematically showing an apparatus for automatic gain control of a sensor in accordance with an embodiment of the present invention;

FIG. 2 is a block diagram schematically showing a margin calculation unit of an apparatus for automatic gain control of a sensor in accordance with another embodiment of the present invention;

FIG. 3 is a block diagram schematically showing a sensor apparatus in accordance with another embodiment of the present invention;

FIG. 4 is a graph showing a change in a gap between a peak value of a compensated sensor signal and a target value;

FIG. 5 is a flowchart schematically showing a method for automatic gain control of a sensor in accordance with another embodiment of the present invention;

FIG. 6 is a flowchart schematically showing a margin calculation step in a method for automatic gain control of a sensor in accordance with an embodiment of the present invention; and

FIG. 7 is a flowchart schematically showing a method for automatic gain control of a sensor in accordance with an embodiment of the present invention.

### DETAILED DESCRIPTION OF THE PREFERABLE EMBODIMENTS

Embodiments of the present invention to achieve the above-described objects will be described with reference to the accompanying drawings. In this description, the same elements are represented by the same reference numerals, and additional description which is repeated or limits interpretation of the meaning of the invention may be omitted.

In this specification, when an element is referred to as being “connected or coupled to” or “disposed in” another element, it can be “directly” connected or coupled to or “directly” disposed in the other element or connected or coupled to or disposed in the other element with another element interposed therebetween, unless it is referred to as being “directly coupled or connected to” or “directly disposed in” the other element.

Although the singular form is used in this specification, it should be noted that the singular form can be used as the concept representing the plural form unless being contradictory to the concept of the invention or clearly interpreted otherwise. It should be understood that the terms such as “having”, “including”, and “comprising” used herein do not preclude existence or addition of one or more other elements or combination thereof.

First, an apparatus for automatic gain control of a sensor in accordance with a first embodiment of the present invention will be specifically described with reference to the drawings. At this time, the reference numeral that is not mentioned in the reference drawing may be the reference numeral that represents the same element in another drawing.

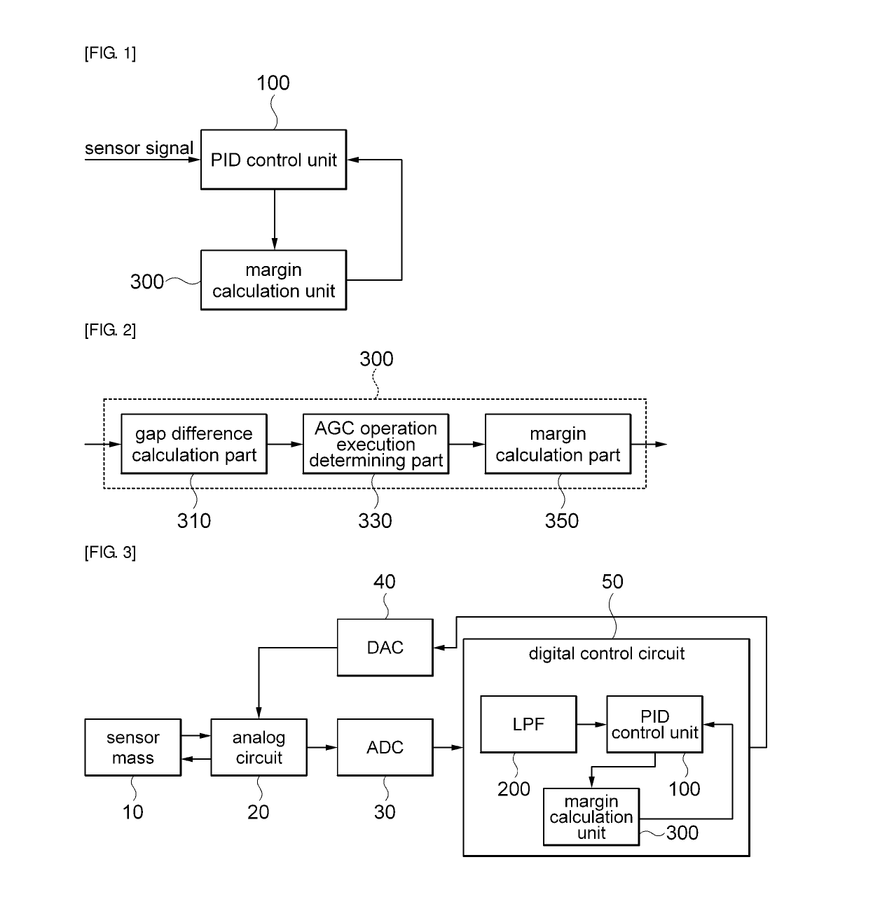

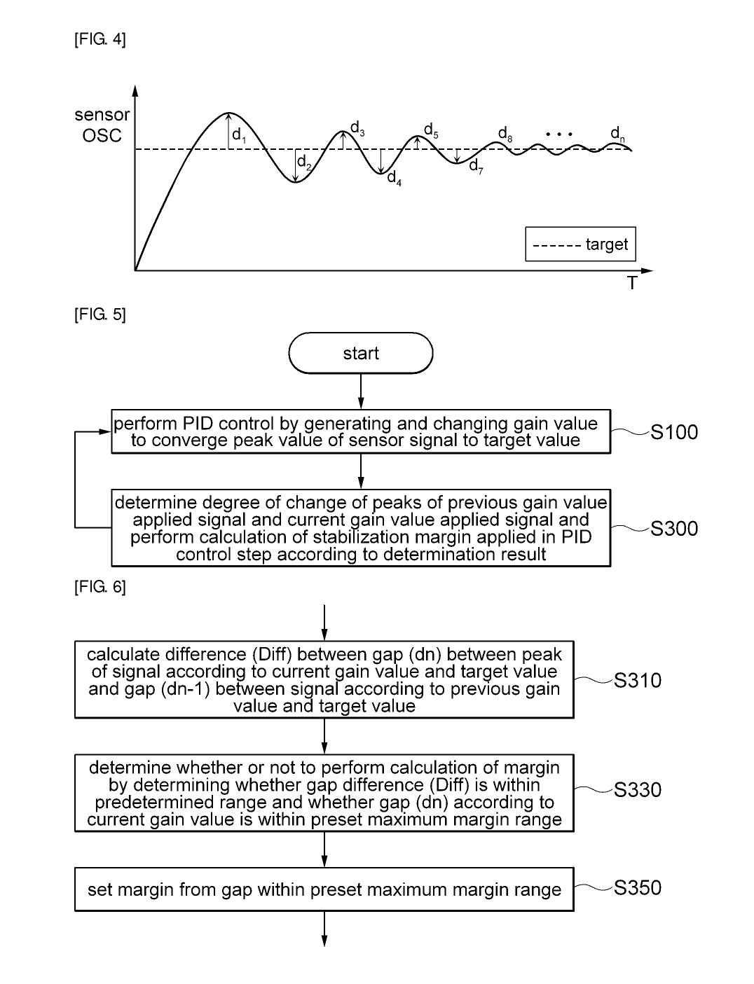

FIG. 1 is a block diagram schematically showing an apparatus for automatic gain control of a sensor in accordance with an embodiment of the present invention, FIG. 2 is a block diagram schematically showing a margin calculation unit of an apparatus for automatic gain control of a sensor in accordance with another embodiment of the present invention, and FIG. 4 is a graph showing a change in a gap between a peak value of a compensated sensor signal and a target value.

Referring to FIG. 1, an apparatus for automatic gain control of a sensor in accordance with an example includes a PID control unit 100 and a margin calculation unit 300.

At this time, the PID control unit 100 performs PID control by generating and changing a gain value to converge a peak value of a sensor signal output as a vibration output signal according to movement or position of an object or external force to a target value. At this time, the PID control unit 100 performs the PID control to output a gain value applied compensated sensor signal. A sensor, which outputs a vibration output signal according to movement or position of an object or external force, may be, for example, a gyro sensor, an acceleration sensor, a vibration sensor, a gravity sensor, etc. In an example, the sensor signal output as the vibration output signal may be a gyro sensor signal.

The PID control is a feedback control method that maintains a compensated output according to a combination of proportional control, integral control, and derivative control connected in parallel at a target value which is a reference voltage and controls a PID control output to converge to the target value by generating and/or changing a compensated gain value based on an error between the compensated output and the target value. The PID control unit 100 outputs the compensated sensor signal by applying the gain value according to the PID control to the sensor signal.

An operation of the PID control unit 100 will be described with reference to FIG. 4. At this time, FIG. 4 is a graph showing a change in a gap between a peak value of a compensated sensor signal and a target value and explains a margin calculation process of automatic gain control (AGC) proposed in the present embodiment. The calculation results of the PID control unit 100 applied to an AGC operation are mostly calculated as in FIG. 4 through coefficient optimization. At this time, each of d₁, d₂, d₃, . . . dₙ shown in FIG. 4 represents a difference, that is, a gap between the peak value of the compensated sensor signal through the PID control unit 100 and the target value. Further, a sensor OSC peak of FIG. 4 represents an output of the compensated sensor signal through the PID control unit 100. The present embodiment intends to obtain a margin value by the margin calculation unit 300 using the d₁, d₂, d₃, . . . dₙ values shown in FIG. 4. Most of the d₁, d₂, d₃, . . . dₙ values have the following characteristics.

d₁>d₂>d₃> . . . >dₙ₋₂≈dₙ₋₁≈dₙ

At this time, in relation to the dₙ values, the AGC operation process can be divided largely into two processes. The first step of the AGC operation process is a step of generating and applying the gain value for converging the peak value of the sensor signal output from the sensor to the target value. At this time, it is characterized in that a relatively large gain value is applied by initial operation so that there is a great change in the peak value of the compensated sensor signal. That is, there is a great change in the difference, that is, the gap between the peak value of the compensated sensor signal and the target value. For example, in the first step, overshoot may occur.

The second step of the AGC operation process is a step in which the peak value of the compensated sensor signal almost converges to the target value but doesn't completely match with the target value and thus continuously oscillates around the target value. At this time, a variation of the peak of the compensated sensor signal is relatively smaller than the first step, and the peak value of the compensated sensor signal oscillates to a constant value with almost no variation in the difference, that is, the gap between the target value and the peak value of the compensated sensor signal. It is required to stabilize AGC by applying a margin greater than the value oscillated in the second step. At this time, the required margin may be set or calculated by the following margin calculation unit 300.

Next, the margin calculation unit 300 will be specifically described with reference to FIGS. 1 and/or 2.

The margin calculation unit 300 determines the degree of change of peaks of a previous gain value applied compensated sensor signal and a current gain value applied compensated sensor signal. At this time, the margin calculation unit 300 performs calculation of a margin for stabilizing the compensated sensor signal in the PID control performing step according to the result of determination of the degree of change. At this time, the margin is to remove a phenomenon that the compensated sensor signal through the PID control unit 100 continuously oscillates around the target value and means a range in which the compensated sensor signal is stabilized.

By calculating or setting an AGC margin through the margin calculation unit 300 in the present embodiment, it is possible to adaptively apply an optimized margin to various sensors. In the AGC operation process, in the prior art, as the AGC operation is processed by applying a large margin value fixed as an external register value, an oscillation phenomenon is latent since performance of AGC may be unnecessarily deteriorated or it is not possible to represent performance of all sensors. However, in the present embodiment, it is possible to adaptively apply an AGC margin to various sensor control systems by adaptively calculating a margin value through the margin calculating unit.

In an example, the margin calculation unit 300 doesn't perform the calculation of the margin when a difference (Diff) between a gap (dₙ) between the peak of the current gain value applied compensated sensor signal and the target value and a gap (dₙ₋₁) between the peak according to the previous gain value and the target value is out of a predetermined range, and performs the calculation of the margin when the difference (Diff) is within the predetermined range and thus the peak values are approximate. That is, a requirement of the calculation of the margin by the margin calculation unit 300 is that the difference (Diff) between the gap (dₙ) between the peak of the current gain value applied compensated sensor signal and the target value and the gap (dₙ₋₁) between the peak according to the previous gain value and the target value reaches within the predetermined range.

For example, referring to FIG. 4, when the dₙ₋₁ value is relatively greater than the dₙ value by comparing the gap (dₙ₋₁) value according to the previous gain value and the gap (dₙ) value according to the current gain value, that is, when the difference (Diff) between the gap (dₙ₋₁) and the gap (dₙ) is out of the predetermined range, it is determined as the first step of the above-described AGC operation process, that is, the step of generating the gain value for converging the peak value of the current sensor signal to the target value. In this step, it is maintained in a standby state without performing any operations for the generation of the margin. When the dₙ₋₁ value and the dₙ value are approximate while continuing the AC operation, that is, when the difference (Diff) between the gap (dₙ₋₁) and the gap (dₙ) enters within the predetermined range, the second step of the above-described AGC operation process starts and the calculation of the margin starts.

At this time, the margin calculation unit 300 may set the margin from the gap between the peak of the compensated sensor signal in the second step of the above-described AGC operation process and the target value. For example, the gap values between the peak of the compensated sensor signal in the second step of the AGC operation process and the target value are observed for a predetermined time interval, and the largest value among them, not one dₙ value obtained in the second step of the above-described AGC operation process, may be determined as the margin value. Even in case of the gap values oscillating around the target value, since there is an error between them, the maximum gap value among the gap values for the predetermined time interval can be set as the margin as above.

A reference of the above-described predetermined range may be appropriately set through a test etc. For example, the reference of the predetermined range may be a range in which a ratio of the gap difference (Diff) to the gap (dₙ) according to the current gain value is 5% but is not limited thereto. That is, when the ratio of the gap difference (Diff) to the gap (dₙ) according to the current gain value is out of 5%, the calculation of the margin is not performed and the PID feedback control is continuously performed. When the ratio of the gap difference (Diff) to the gap (dₙ) according to the current gain value reaches within 5%, the calculation of the margin is performed.

Referring to FIG. 4, while most of the AGC operations pass through the first step and the second step of the above-described AGC operation process in the same form as FIG. 4, a gain value is applied to converge to a target value. However, when applying a very small PID coefficient or a very large PID coefficient, overshoot may not occur or overshoot may continuously occur so that oscillation may occur without converging to the target value as in the second step of the above-described AGC operation process. Two cases will be described.

For example, when a small PID coefficient value is applied to slowly converge to the target value, the PID coefficient value may be adjusted to pass through the first and second steps of the AGC operation process as in FIG. 4. However, without the adjustment of the PID coefficient value, it is possible to generate and apply a margin value by determining that the first step of the above-described AGC operation process in which the AGC operation is performed so that the dₙ value is relatively greatly changed is omitted and the second step of the AGC operation process in which there is no change in the dₙ value starts.

On the other hand, when a large PID coefficient value is applied so that AGC oscillates, the PID coefficient value may be adjusted to pass through the first and second steps of the AGC operation process as in FIG. 4. However, if it is before adjusting the PID coefficient value, when the large PID coefficient value is applied so that the AGC oscillates, since there is no first step of the AGC operation in which the AGC operation is performed so that the dₙ value is relatively greatly changed and there is almost no deviation of the dₙ value, it may be determined as the same as when the small PID value is applied. However, in this case, when the AGC actually oscillates, there may be a problem that a very large margin value is applied to forcedly stabilize the AGC operation by determining not as oscillation due to erroneous application of the PID coefficient value but as oscillation in the process of converging to the target value like the case of the small PID coefficient value. In order to overcome this problem, a preset maximum margin (Marginₘₐₓ) value can be applied.

Accordingly, in an example, the margin calculation unit 300 can calculate the margin when the degree of change of the peak of the compensated sensor signal converges within a predetermined range so that the peak values of the compensated sensor signal are approximate to each other and the gap dₙ between the peak of the current gain value applied compensated sensor signal and the target value is within the preset maximum margin (Marginₘₐₓ) range. That is, as requirements for performing the calculation of the margin, a first requirement that the degree of change of the peak of the compensated sensor signal converges within the predetermined range and a second requirement that the gap dₙ between the peak of the current gain value applied compensated sensor signal and the target value is within the preset maximum margin range may be required. For example, the maximum margin (Margin_{MAX}) may be preset from the value obtained through a test etc.

Accordingly, the margin calculated by the margin calculation unit 300 can be formed as only a value smaller than the maximum margin. For example, when oscillating, the calculation of the margin isn't performed and the PID coefficient value is adjusted, and when slowly converging, since the gap dₙ value is formed as a value smaller than the maximum margin, it is possible to stabilize AGC by performing the calculation of the margin. When the degree of change of the peak of the compensated sensor signal converges within the predetermined range so that the peak values of the compensated signal are approximate to each other, it is possible to determine whether it is an AGC oscillation state or oscillation around the target value as follows.

When the gap dₙ between the peak of the compensated sensor signal and the target value maximum margin (Margin_{MAX}), it is determined as an AGC oscillation state, and when the gap dₙ between the peak of the compensated sensor signal and the target value maximum margin (Margin_{MAX}), it is determined as oscillation around the target value.

Further, the margin calculation unit 300 may set the margin from the gap between the peak of the compensated sensor signal and the target value which is within the preset maximum margin range. In an example, the margin calculation unit 300 may set the maximum gap among the gaps between the peak of the compensated sensor signal and the target value for a predetermined interval from when the gap (dₙ) between the peak of the current gain value applied compensated sensor signal and the target value is within the preset maximum margin range, as the margin. For example, the predetermined interval from when the gap (dₙ) between the peak of the compensated sensor signal and the target value is within the preset maximum margin range may be obtained through a test etc, and a minimum value that can bring a stable margin may be applied. That is, the margin may be determined by the following formula. At this time, m is the predetermined interval.

Margin=MAX{dₙ,dₙ₊₁,dₙ₊₂, . . . ,dₙ₊ₘ}

Continuously, the margin calculation unit 300 will be specifically described with reference to FIG. 2. In accordance with an example, the margin calculation unit 300 may include a gap difference calculation part 310, an AGC operation execution determining part 330, and a margin calculation part 350.

At this time, the gap difference calculation part 310 may calculate the difference (Diff) between the gap (dₙ) between the peak of the current gain value applied compensated sensor signal and the target value and the gap (dₙ₋₁) between the peak according to the previous gain value and the target value. For example, at this time, the gap (dₙ) between the peak of the compensated sensor signal and the target value may be calculated in the PID control process by the PID control unit 100. When the AGC operation starts, the gap (dₙ) between the peak of the compensated sensor signal and the target value is calculated through comparison between the peak value of the current compensated sensor signal and the target value, and the gap difference calculation part 310 calculates the variation of the gap (dₙ) value, that is, the difference (Diff) between the gap (dₙ₋₁) between the peak according to the previous gain value and the target value and the gap (dₙ) between the peak of the current gain value applied compensated sensor signal and the target value.

Next, referring to FIG. 2, the AGC operation execution determining part 330 determines whether or not to execute the calculation of the margin by determining whether the gap difference (Diff) calculated by the gap difference calculation part 310 is within the predetermined range and whether the gap (dₙ) between the compensated sensor signal according to the current gain value and the target value is within the preset maximum margin (Margin_{MAX}). That is, the AGC operation execution determining part 330 determines whether the first requirement that the gap difference (Diff) should be within the predetermined range and the second requirement that the gap (dₙ) according to the current gain value should be within the preset maximum margin (Margin_{MAX}) are satisfied or not as margin operation execution requirements. For example, at this time, the AGC operation execution determining part 330 may determine whether the second requirement is satisfied or not when the first requirement is satisfied. For example, the range in which the peak values of the compensated sensor signal are approximate to each other may be determined as the predetermined range for determining whether the gap difference (Diff) is within the predetermined range. Further, the maximum margin (Margin_{MAX}) may be preset from the value obtained through a test etc.

For example, first, the AGC operation execution determining part 330 determines which step of the AGC operation the current process is. That is, when the variation of the gap (dₙ₋₁) value according to the previous gain value and the gap (dₙ) value according to the current gain value, that is, the difference (Diff) is out of the predetermined range, the AGC operation execution determining part 330 determines as the step in which the AGC operation is continuously executed to prevent the margin calculation part 350 from performing the calculation of the margin. On the other hand, when the variation of the gap (dₙ₋₁) value according to the previous gain value and the gap (dₙ) value according to the current gain value, that is, the difference (Diff) is little or within the predetermined range, the AGC operation execution determining part 330 determines as the state in which the AGC operation continues but doesn't converge to the target and oscillates around the target to allow the margin calculation part 350 to perform the calculation of the margin. Continuously, when the variation of the gap (dₙ₋₁) value according to the previous gain value and the gap (dₙ) value according to the current gain value, that is, the difference (Diff) is little or within the predetermined range, the AGC operation execution determining part 330 compares the gap (dₙ) value between the compensated sensor signal and the target value with the preset maximum margin (Margin_{MAX}) to determine whether oscillation occurs and determines whether the current result is a result by the oscillation.

In an example, the AGC operation execution determining part 330 may determine whether or not to execute the calculation of the margin when the gap difference (Diff) is within the predetermined range and the gap (dₙ) according to the current gain value is within the preset maximum margin range. At this time, when the gap difference (Diff) is out of the predetermined range or the gap (dₙ) according to the current gain value is out of the preset maximum margin range, the calculation of the margin isn't performed and the PID control is continuously performed by generating and changing the gain value by the PID control unit 100.

In another example, when the AGC operation execution determining part 330 determines whether the difference calculated by the gap difference calculation part 310 is within the predetermined range, the reference of the predetermined range may be the range in which the ratio of the gap difference (Diff) to the gap (dₙ) according to the current gain value is 5% but is not limited thereto.

Next, referring to FIG. 2, the margin calculation part 350 may set the margin from the gap within the preset maximum margin (Margin_{MAX}) range when the execution of the calculation of the margin is determined by the AGC operation execution determining part 330. When the current result of the AGC value is determined as neither AGC operation state nor oscillation state through the determination process of the AGC operation execution determining part 330, the margin calculation part 350 can calculate the margin value through the gap value between the current compensated sensor signal and the target value. However, even in case of the gap value oscillating around the target, since a minute error may occur between the corresponding values, it is possible to set the margin by the largest value among the gap values between a series of compensated sensor signals and the target value for a predetermined time interval rather than calculating the margin by only the gap between one compensated sensor signal and the target value.

That is, in an example, the margin calculation part 350 may set the maximum margin among the gaps between the peaks of the compensated sensor signal and the target value for the predetermined interval from when the gap (dₙ) according to the current gain value is within the preset maximum margin range, as the margin. For example, the margin may be determined by the following formula. At this time, m is the predetermined interval and may be determined through a test etc. For example, a minimum value that can bring a stable margin may be applied.

Margin=MAX{dₙ,dₙ₊₁,dₙ₊₂, . . . dₙ₊ₘ}

Next, a sensor apparatus in accordance with a second embodiment of the present invention will be specifically described with reference to the drawings. At this time, the apparatus for automatic gain control of a sensor in accordance with the above-described first embodiment and FIGS. 1, 2, and 4 will be referenced. Accordingly, repeated descriptions may be omitted.

FIG. 3 is a block diagram schematically showing a sensor apparatus in accordance with another embodiment of the present invention. The margin calculation unit 300 shown in FIG. 2 can be equally applied to the sensor apparatus in FIG. 3.

Referring to FIG. 3, a sensor apparatus in accordance with an example includes a sensor mass 10, an analog circuit 20, an analog-digital conversion (ADC) unit 30, a digital control unit 50, and a digital-analog conversion (DAC) unit 40. For example, in an example, the sensor apparatus may be a gyro sensor apparatus.

At this time, the sensor mass 10 provides a vibration output according to movement or position of an object or external force. A sensor, which outputs a vibration output signal according to movement or position of an object or external force, may be, for example, a gyro sensor, an acceleration sensor, a vibration sensor, a gravity sensor, etc. In an example, the sensor mass 10 may be a sensor mass of a gyro sensor.

Next, referring to FIG. 3, the analog circuit 20 processes the vibration output of the sensor mass 10 to generate and output an analog sensor signal and provides a resonance signal to the sensor mass 10. For example, the analog circuit 20 processes the vibration output of the sensor mass 10 as an electrical signal to output the electrical signal. That is, the analog circuit 20 processes an output value, which can know a resonant state of the sensor mass, as a signal to provide the signal to the digital control circuit 50 through the ADC 30. Further, the analog circuit 20 provides the resonance signal to the sensor mass 10 according to the signal fed back through the DAC 40 to resonate the sensor mass 10. That is, an AGC function is performed in the order in which a compensated sensor signal compensated according to a gain value generated by the digital control circuit 50 is fed back to the analog circuit 20 through the DAC 40 and applied to the sensor mass 10 again through the analog circuit 20.

Next, referring to FIG. 3, the ADC 30 converts the analog sensor signal into a digital signal to provide the digital signal to the digital control circuit 50. That is, the ADC 30 converts the analog sensor signal into the digital signal for PID control of a PID control unit 100 of the digital control circuit 50.

Further, referring to FIG. 3, the DAC 40 converts an output according to operation performed by the digital control circuit 50 described below into an analog signal to feed back the analog signal to the analog circuit 20. Accordingly, the output of the compensated sensor signal following a target value according to the operation of the digital control circuit 50 is fed back to the analog circuit 20 to be provided as the resonance signal of the sensor mass 10.

Continuously, referring to FIG. 3, the digital control circuit 50 receives the sensor signal converted into the digital signal. An output signal value according to resonance of the sensor mass 10 is received from the analog circuit 20 and transmitted to the digital control circuit 50 through the ADC 30, and an AGC operation for controlling the resonance of the sensor mass 10 is performed by the digital control circuit 50. The digital control circuit 50 generates a gain value that can resonate the sensor mass 10 at a desired target value through signal processing of AGC. In the signal processing process of AGC, an operation for generating the gain value for driving of the sensor mass 10 processed by the digital control circuit 50 is the most important part, and performance of the entire AGC can be evaluated by performance and stability of the corresponding part.

The digital control circuit 50 includes the PID control unit 100 and a margin calculation unit 300. At this time, the digital control circuit 50 performs an AGC operation according to a margin calculated by the margin calculation unit 300. Further, referring to FIG. 3, in an example, the digital control circuit 50 may further include a low-pass filter unit 200.

Specifically, the PID control unit 100 of the digital control circuit 50 performs the PID control by generating and changing the gain value for converging a peak value of the sensor signal output as a vibration output signal according to movement or position of an object or external force to a target value. At this time, the PID control unit 100 performs the PID control to output a gain value applied compensated sensor signal. The PID controlled output by the PID control unit 100 is fed back to the analog circuit 20 through the DAC 40 so that AGC through the PID feedback control is performed.

Continuously, referring to FIG. 3, the margin calculation unit 300 of the digital control circuit 50 determines the degree of change of peaks of a previous gain value applied compensated sensor signal and a current gain value applied compensated sensor signal and perform calculation of a margin for stabilizing the compensated sensor signal according to the result of determination of the degree of change. At this time, the margin means a range in which the compensated sensor signal through the PID control unit 100 is stabilized. For example, the margin calculation unit 300 may perform the calculation of the margin when a difference (Diff) between a gap (dₙ) between the peak of the current gain value applied compensated sensor signal and the target value and a gap (dₙ₋₁) between the peak according to the previous gain value and the target value converges within a predetermined range so that the peak values are approximate. Further, the margin calculation unit 300 may perform the calculation of the margin when the degree of change of the peak of the compensated sensor signal converges within the predetermined range so that the peak values of the compensated sensor signal are approximate to each other and the gap (dₙ) between the peak of the current gain value applied compensated sensor signal and the target value is within a preset maximum margin (Margin_{MAX}) range. In addition, the margin calculation unit 300 may set the margin from the gap between the peak of the compensated sensor signal and the target value which is within the preset maximum margin range.

Referring to FIG. 2, in an example, the margin calculation unit 300 of the digital control circuit 50 may include a gap difference calculation part 310, an AGC operation execution determining part 330, and a margin calculation part 350. Referring to FIG. 2, the gap difference calculation part 310 may calculate the difference (Diff) between the gap (dₙ) between the peak of the current gain value applied compensated sensor signal and the target value and the gap (dₙ₋₁) between the peak according to the previous gain value and the target value.

Further, referring to FIG. 2, the AGC operation execution determining part 330 determines whether or not to perform the calculation of the margin by determining whether the gap difference (Diff) calculated by the gap difference calculation part 310 is within the predetermined range and whether the gap (dₙ) according to the current gain value is within the preset maximum margin (Margin_{MAX}) range. At this time, a reference of the predetermined range may be appropriately set through a test etc. For example, the reference of the predetermined range may be a range in which a ratio of the gap difference (Diff) to the gap (dₙ) according to the current gain value is 5%. Further, the maximum margin (Margin_{MAX}) may be preset from the value obtained through a test etc.

Continuously, referring to FIG. 2, the margin calculation part 350 may set the margin from the gap within the preset maximum margin (Margin_{MAX}) range when the execution of the calculation of the margin is determined by the AGC operation execution determining part 330. For example, in an example, the margin calculation part 350 may set the maximum margin among the gaps between the peaks of the compensated sensor signal and the target value for a predetermined interval from when the gap (dₙ) according to the current gain value is within the preset maximum margin range, as the margin. At this time, the predetermined interval for searching the maximum gap may be determined through a test etc, and a minimum value that can bring a stable margin may be applied as the predetermined interval.

Again, referring to FIG. 3, in an example, the digital control circuit 50 may further include the low-pass filter unit 200. At this time, the low-pass filter unit 200 receives the sensor signal converted into the digital signal, removes noise of the received signal, and provides the noise-removed signal to the PID control unit 100.

Next, a method for automatic gain control of a sensor in accordance with a third embodiment of the present invention will be specifically described with reference to the drawings. At this time, the apparatus for automatic gain control of a sensor in accordance with the above-described first embodiment, the sensor apparatus in accordance with the above-described second embodiment, and FIGS. 1 to 4 will be referenced. Accordingly, repeated descriptions may be omitted.

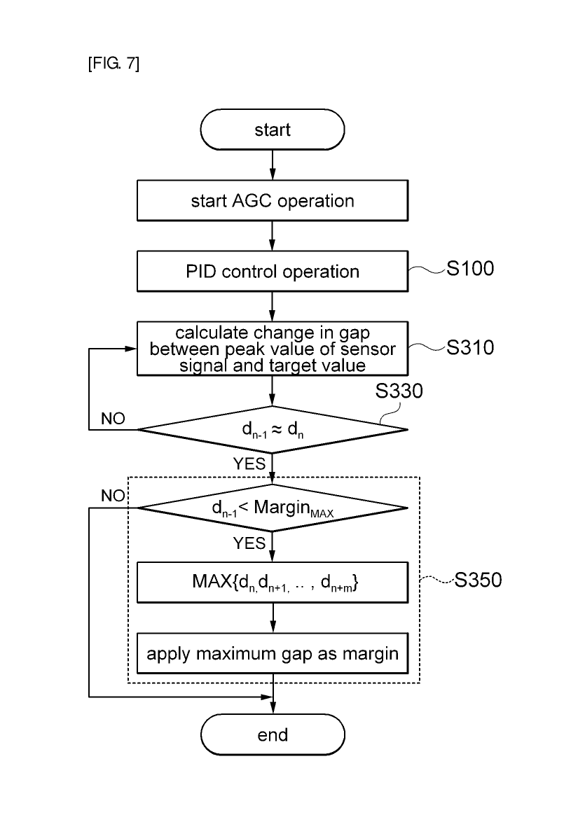

FIG. 5 is a flowchart schematically showing a method for automatic gain control of a sensor in accordance with another embodiment of the present invention, FIG. 6 is a flowchart schematically showing a margin calculation step in the method for automatic gain control of a gain in accordance with an embodiment of the present invention, and FIG. 7 is a flowchart schematically showing the method for automatic gain control of a sensor in accordance with an embodiment of the present invention.

Referring to FIGS. 5 and/or 7, a method for automatic gain control of a sensor in accordance with an example includes a PID control performing step (S100) and a margin calculation step (S300).

First, in the PID control performing step (S100), PID control is performed by generating and changing a gain value to converge a peak value of a sensor signal output as a vibration output signal according to movement or position of an object or external force to a target value. At this time, a gain value applied compensated sensor signal is output while the PID control is performed. A sensor, which outputs a vibration output signal according to movement or position of an object or external force, may be, for example, a gyro sensor, an acceleration sensor, a vibration sensor, a gravity sensor, etc. In an example, a sensor signal output as a vibration output signal may be a gyro sensor signal.

Next, in the margin calculation step (S300), the degree of change of a previous gain value applied compensated sensor signal and a current gain value applied compensated sensor signal is determined. Further, in the margin calculation step (S300), according to the result of determination of the degree of change of the peak of the compensated sensor signal, a stabilization margin of the sensor signal which is applied to the PID control performing step is calculated. At this time, the margin means a range in which the compensated sensor signal through the PID control is stabilized.

For example, in the margin calculation step (S300), the calculation of the margin may be performed when a difference (Diff) between a gap (dₙ) between the peak of the current gain value applied compensated sensor signal and the target value and a gap (dₙ₋₁) between the peak according to the previous gain value and the target value converges within a predetermined range so that the peak values are approximate. Further, in the margin calculation step (S300), the calculation of the margin may be performed when the degree of change of the peak of the compensated sensor signal converges within the predetermined range so that the peak values of the compensated sensor signals are approximate to each other and the gap (dₙ) between the peak of the current gain value applied compensated sensor signal and the target value is within a preset maximum margin (Margin_{MAX}) range. Further, in the margin calculation step (S300), the margin may be set from the gap between the peak of the compensated sensor signal and the target value which is within the preset maximum margin range.

Specifically describing with reference to FIGS. 6 and/or 7, in an example, the margin calculation step may include a gap difference calculation step (S310), an AGC operation execution determining step (S330), and a margin setting step (S350).

First, referring to FIGS. 6 and/or 7, in the gap difference calculation step (S310), the difference (Diff) between the gap (dₙ) between the peak of the current gain value applied compensated sensor signal and the target value and the gap (dₙ₋₁) between the peak according to the previous gain value and the target value is calculated.

Next, referring to FIGS. 6 and/or 7, in the AGC operation execution determining step (S330), it is determined whether or not to execute the calculation of the margin by determining whether the gap difference (Diff) calculated in the gap difference calculation step (S310) is within the predetermined range and whether the gap (dₙ) according to the current gain value is within the preset maximum margin (Margin_{MAX}) range. At this time, a reference of the predetermined range may be appropriately set through a test etc. For example, the reference of the predetermined range may be a range in which a ratio of the gap difference (Diff) to the gap (dₙ) according to the current gain value is 5%. Further, the maximum margin (Margin_{MAX}) may be preset from the value obtained through a test etc.

At this time, in accordance with an example, in the AGC operation execution determining step (S330), it is determined whether or not to execute the calculation of the margin when the gap difference (Diff) is within the predetermined range and the gap (dₙ) according to the current gain value is within the preset maximum margin range. On the other hand, the calculation of the margin is not executed when the gap difference (Diff) is out of the predetermined range or the gap (dₙ) according to the current gain value is output of the preset maximum margin range.

Next, referring to FIGS. 6 and/or 7, in the margin setting step (S350), when the execution of the calculation of the margin is determined in the AGC operation execution determining step (S350), the margin is set from the gap within the preset maximum margin range. For example, although not shown, in accordance with an example, in the margin setting step (S350), the maximum gap among the gaps between the peak of the compensated sensor signal and the target value for a predetermined time interval from when the gap (dₙ) according to the current gain value is within the preset maximum margin range may be set as the margin. At this time, the predetermined interval for searching the maximum gap may be determined through a test etc, and a minimum value that can bring a stable margin may be applied as the predetermined interval.

According to an embodiment of the present invention, it is possible to perform an AGC operation by calculating a margin in each AGC system itself and applying a minimum adaptive margin value.

Further, it is possible to minimize an AGC error by calculating and applying a margin adaptive to characteristics of each sensor in itself.

Further, according to an embodiment of the present invention, it is possible to converge an AGC execution value to a target value as close as possible by always executing AGC with a minimum margin in the corresponding system as well as removing oscillation around a target which is a problem when executing AGC. Thus, it is possible to minimize an AGC error.

It is apparent that various effects which have not been directly mentioned according to the various embodiments of the present invention can be derived by those skilled in the art from various constructions according to the embodiments of the present invention.

The above-described embodiments and the accompanying drawings are provided as examples to help understanding of those skilled in the art, not limiting the scope of the present invention. Further, embodiments according to various combinations of the above-described components will be apparently implemented from the foregoing specific descriptions by those skilled in the art. Therefore, the various embodiments of the present invention may be embodied in different forms in a range without departing from the essential concept of the present invention, and the scope of the present invention should be interpreted from the invention defined in the claims. It is to be understood that the present invention includes various modifications, substitutions, and equivalents by those skilled in the art.

1. An apparatus for automatic gain control of a sensor, comprising:
a PID control unit for outputting a gain value applied compensated sensor signal by performing PID control while generating and changing a gain value to converge a peak value of a sensor signal output as a vibration output signal according to movement or position of an object or external force to a target value; and
a margin calculation unit for determining the degree of change of peaks of a previous gain value applied compensated sensor signal and a current gain value applied compensated sensor signal and performing calculation of a margin for stabilizing the compensated sensor signal in the PID control performing step according to the result of determination of the degree of change.

2. The apparatus for automatic gain control of a sensor according to claim 1, wherein the margin calculation unit doesn't perform the calculation of the margin when a difference between a gap between the peak of the current gain value applied compensated sensor signal and the target value and a gap between the peak according to the previous gain value and the target value is out of a predetermined range and performs the calculation of the margin when the difference is within the predetermined range and the peak values are approximate.

3. The apparatus for automatic gain control of a sensor according to claim 1, wherein the margin calculation unit calculates the margin when the degree of change is within the predetermined range, the peak values are approximate, and the gap between the peak of the current gain value applied compensated sensor signal and the target value is within a preset maximum margin range.

4. The apparatus for automatic gain control of a sensor according to claim 3, wherein the margin calculation unit sets the maximum gap among the gaps between the peak of the compensated sensor signal and the target value for a predetermined interval from when the gap between the peak of the current gain value applied compensated sensor signal and the target value is within the preset maximum margin range, as the margin.

5. The apparatus for automatic gain control of a sensor according to claim 1, wherein the margin calculation unit comprises:
a gap difference calculation part for calculating the difference (Diff) between the gap (dₙ) between the peak of the current gain value applied compensated sensor signal and the target value and the gap (dₙ₋₁) between the peak according to the previous gain value and the target value;
an AGC operation execution determining part for determining whether or not to execute the calculation of the margin by determining whether the gap difference (Diff) calculated by the gap difference calculation part is within the predetermined range and whether the gap (dₙ) according to the current gain value is within the preset maximum margin range; and
a margin calculation part for setting the margin from the gap within the preset maximum margin range when the execution of the calculation of the margin is determined by the AGC operation execution determining part.

6. The apparatus for automatic gain control of a sensor according to claim 5, wherein the AGC operation execution determining part determines the execution of the calculation of the margin when the gap difference (Diff) is within the predetermined range and the gap (dₙ) according to the current gain value is within the preset maximum margin range, and continuously performs the PID control without executing the calculation of the margin by generating and changing the gain value through the PID control unit when the gap difference (Diff) is out of the predetermined range or the gap (dₙ) according to the current gain value is out of the preset maximum margin range.

7. The apparatus for automatic gain control of a sensor according to claim 5, wherein when the AGC operation execution determining part determines whether the difference calculated by the gap difference calculation part is within the predetermined range, a reference of the predetermined range is a range in which a ratio of the gap difference (Diff) to the gap (dₙ) according to the current gain value is 5%.

8. The apparatus for automatic gain control of a sensor according to claim 5, wherein the margin calculation part sets the maximum gap among the gaps between the peak of the compensated sensor signal and the target value for the predetermined interval from when the gap (dₙ) according to the current gain value is within the preset maximum margin range, as the margin.

9. The apparatus for automatic gain control of a sensor according to claim 1, wherein the sensor signal output as a vibration output signal is a gyro sensor signal.

10. A sensor apparatus comprising:
a sensor mass for providing a vibration output according to movement or position of an object or external force;
an analog circuit for generating and outputting an analog sensor signal by processing the vibration output of the sensor mass and providing a resonance signal to the sensor mass;
an analog-digital conversion unit for converting the analog sensor signal into a digital signal;
a digital control circuit for receiving the sensor signal converted into the digital signal, comprising a PID control unit for outputting a gain value applied compensated sensor signal by performing PID control while generating and changing a gain value to converge a peak value of the sensor signal output as the vibration output signal according to the movement or position of the object or the external force to a target value and a margin calculation unit for determining the degree of change of peaks of a previous gain value applied compensated sensor signal and a current gain value applied compensated sensor signal and performing calculation of a margin for stabilizing the compensated sensor signal according to the result of determination of the degree of change, and performing an automatic gain control operation according to the margin; and
a digital-analog conversion unit for converting an output according to the operation performed by the digital control circuit into an analog signal to feed back the analog signal to the analog circuit.

11. The sensor apparatus according to claim 10, wherein the margin calculation unit of the digital control circuit comprises:
a gap difference calculation part for calculating a difference (Diff) between a gap (dₙ) between the peak of the current gain value applied compensated sensor signal and the target value and a gap (dₙ₋₁) between the peak according to the previous gain value and the target value;
an AGC operation execution determining part for determining whether or not to execute the calculation of the margin by determining whether the gap difference (Diff) calculated by the gap difference calculation part is within a predetermined range and whether the gap (dₙ) according to the current gain value is within a preset maximum margin range; and
a margin calculation part for setting the margin from the gap within the preset maximum margin range when the execution of the calculation of the margin is determined by the AGC operation execution determining part.

12. The sensor apparatus according to claim 11, wherein the margin calculation part sets the maximum gap among the gaps between the peak of the compensated sensor signal and the target value for a predetermined interval from when the gap (dₙ) according to the current gain value is within the preset maximum margin range, as the margin.

13. The sensor apparatus according to claim 10, wherein the digital control circuit further comprises a low-pass filter unit for receiving the sensor signal converted into the digital signal, removing noise of the received signal, and providing the noise-removed signal to the PID control unit.

14. The sensor apparatus according to claim 10, wherein the sensor apparatus is a gyro sensor apparatus.

15. A method for automatic gain control of a sensor, comprising:
a PID control performing step of outputting a gain value applied compensated sensor signal by performing PID control while generating and changing a gain value to converge a peak value of a sensor signal output as a vibration output signal according to movement or position of an object or external force to a target value; and
a margin calculation step of determining the degree of change of peaks of a previous gain value applied compensated sensor signal and a current gain value applied compensated sensor signal and performing calculation of a stabilization margin of the sensor signal applied to the PID control performing step according to the result of determination of the degree of change.

16. The method for automatic gain control of a sensor according to claim 15, wherein the margin calculation step comprises:
a gap difference calculation step of calculating a difference (Diff) between a gap (dₙ) between the peak of the current gain value applied compensated sensor signal and the target value and a gap (dₙ₋₁) between the peak according to the previous gain value and the target value;
an AGC operation execution determining step of determining whether or not to execute the calculation of the margin by determining whether the gap difference (Diff) calculated in the gap difference calculation step is within a predetermined range and whether the gap (dₙ) according to the current gain value is within a preset maximum margin range; and
a margin setting step of setting the margin from the gap within the preset maximum margin range when the execution of the calculation of the margin is determined in the AGC operation execution determining step.

17. The method for automatic gain control of a sensor according to claim 16, wherein in the AGC operation execution determining step, the execution of the calculation of the margin is determined when the gap difference (Diff) is within the predetermined range and the gap (dₙ) according to the current gain value is within the preset maximum margin range, and the calculation of the margin is not performed when the gap difference (Diff) is out of the predetermined range or the gap (dₙ) according to the current gain value is out of the preset maximum margin range.

18. The method for automatic gain control of a sensor according to claim 16, wherein in the margin setting step, the maximum gap among the gaps between the peak of the compensated sensor signal and the target value for a predetermined interval from when the gap (dₙ) according to the current gain value is within the preset maximum margin range is set as the margin.
